(19) United States
(12) Patent Application Publication
(10) Pub. No.: US 2026/0082738 A1
(43) Pub. Date: Mar. 19, 2026

(54) MICRO LIGHT-EMITTING PIXEL STRUCTURE AND MANUFACTURING METHOD THEREOF

(71) Applicant: JADE BIRD DISPLAY (SHANGHAI) LIMITED, Shanghai Pilot Free Trade Zone (CN)

(72) Inventors: Jian GUO, Shanghai (CN); Huiwen XU, Shanghai (CN); Qiming LI, Albuquerque, NM (US)

(73) Assignee: JADE BIRD DISPLAY (SHANGHAI) LIMITED, Shanghai (CN)

(21) Appl. No.: 19/110,099

(22) PCT Filed: Sep. 9, 2022
(86) PCT No.: PCT/CN2022/117988

§ 371 Date: Mar. 10, 2025

(51) Int. Cl. H10H 20/832; H10H 20/01; H10H 20/812; H10H 20/821; H10H 20/825; H10H 29/01; H10H 29/39; H10H 29/41; H10H 29/80

(52) U.S. Cl. CPC H10H 20/835; H10H 20/032; H10H 20/812; H10H 20/821; H10H 20/825; H10H 29/011; H10H 29/012; H10H 29/032; H10H 29/0364; H10H 29/39; H10H 29/41; H10H 29/8321

(57) ABSTRACT

A pixel structure for improving light emitting efficiency is disclosed in the present disclosure. The pixel structure includes a pixel lens, a negative electrode pad layer, a conductive semiconductor layer, a quantum well, an isolation layer, a positive electrode layer, a dielectric layer and an integrated circuit (IC) chip layer from top to bottom, and the quantum well is arranged inside the conductive semiconductor layer. A three-surface covering reflective layer is arranged between the lower surface of the conductive semiconductor layer and the top of the positive electrode layer. The conductive semiconductor layer comprises an inverted trapezoidal semiconductor part and a continuous planarization layer. The bevels on the two sides of the inverted trapezoidal semiconductor part converge and reflect the light emitted by the quantum well in the direction of the pixel lens. And the negative electrode pad layer is arranged on the continuous planarization layer.

### TECHNICAL FIELD

The present disclosure relates generally to the technical field of displays, in particular to a light emitting pixel structure for reducing light blocking effect and improving light reflecting efficiency, and a manufacturing process thereof.

### BACKGROUND

Display technologies are becoming increasingly important in today's commercial electronic devices. These display panels are widely used in stationary large screens such as liquid crystal display televisions (LCD TVs) and organic light emitting diode televisions (OLED TVs) as well as portable electronic devices such as laptop personal computers, smartphones, tablets and wearable electronic devices.

A Light-Emitting Diode (LED) chip generally includes an Organic Light-Emitting Diode (OLED) chip, a Mini Light-Emitting Diode (Sub-millimeter Light-Emitting Diode) chip or a Micro LED (Micro Meter Light-Emitting Diode) chip and the like. LED is widely applied in the field of illumination. As the LED display screen gradually permeates towards the high-end market, the light emitting efficiency requirement of the LED display screen device is higher.

Pixels are composed of small squares of an image, and the small squares have a clear position and are assigned color values, and the color and position of the small squares determine the appearance of the image. The pixels may be viewed as inseparable units or elements throughout the image. Inseparable means that a pixel cannot be further cut into smaller units or elements, which are present in a single-color cell. Each dot matrix image contains a quantity of pixels that determine the size of the image presented on the screen.

Some implementations disclose a light-emitting diode unit comprising a plurality of pixels for a display and a display device with the light-emitting diode units. The implementations disclose (1) a plurality of pixels, wherein each pixel comprises a first light-emitting unit, a second light-emitting unit and a third light-emitting unit, and that each unit respectively comprises a first conductive semiconductor layer, an active layer and a second conductive semiconductor layer; (2) electric connections with the first light-emitting unit through the third light-emitting unit so as to independently drive the first light-emitting unit through the third light-emitting unit; (3) the second wavelength converter which converts the wavelength of light emitted from the second light emitting unit; and (4) the third wavelength converter which converts the wavelength of the light emitted from the third light emitting unit, wherein the third wavelength converter converts the wavelength of the light to a longer wavelength than the second wavelength converter, the second light emitting unit has a light emitting area greater than that of the first light emitting unit, and the third light emitting unit has a light emitting area greater than that of the second light emitting unit. Due to the use of the light-emitting diode unit comprising a plurality of pixels, the light-emitting unit may be easily attached to the substrate.

However, the pixel structure in those implementations has the following technical problems. Since the light emitted by the light-emitting unit is emitted to the periphery of the light-emitting unit, the light emitted by the display devices, or near-eye augmented reality (AR) devices may only be limited to light emitted by the light-emitting unit towards the lens direction. Meanwhile, the light-blocking situation may exist between the light-emitting unit and the lens, so that the brightness of the light emitted by the light-emitting unit received by the lens only accounts for 50% or less of the light emitted by the light-emitting unit in the pixel. Therefore, the working efficiency of the light-emitting unit is low, and improvements are needed.

As such, it would be desirable to provide a light emitting structure for display panels that addresses the above-mentioned drawbacks, amongst others.

### SUMMARY

There is a need for improved display device designs that improve upon, and help to address the issues and shortcomings of conventional display systems, such as those described above. In particular, there is a need for display panels with improved light efficiency with better images.

The present disclosure relates to the technical field of displays, and discloses a pixel structure for reducing light blocking effect and improving light reflecting efficiency, and a manufacturing process of the pixel structure. The technical problem of low light efficiency of conversion from a pixel light-emitting unit at present is solved.

The present disclosure includes, without limitation, the following exemplary embodiments.

Some exemplary embodiments of the present disclosure include a micro light-emitting pixel structure. The micro light-emitting pixel structure includes: a conductive semiconductor layer, wherein the conductive semiconductor layer has an inverted trapezoidal shape and includes a continuous planarization layer on top of the inverted trapezoidal shape; a quantum well layer for light-emitting, wherein the quantum well layer is within the conductive semiconductor layer; a three-surface covering reflective layer beneath the conductive semiconductor layer, wherein a material of the three-surface covering reflective layer is Ag; a negative electrode pad layer electrically connected to the conductive semiconductor layer; a positive electrode layer electrically connected to the conductive semiconductor layer; and an integrated circuit (IC) chip layer electrically connected to the positive electrode layer.

Some exemplary embodiments of the present disclosure include a micro light-emitting pixel structure. The micro light-emitting pixel structure includes: a conductive semiconductor layer, wherein the conductive semiconductor layer has an inverted trapezoidal shape; a quantum well layer for light-emitting, wherein the quantum well layer is within the conductive semiconductor layer; a three-surface covering reflective layer beneath the conductive semiconductor layer, wherein a material of the three-surface covering reflective layer is Ag; an isolation layer between the conductive semiconductor layer and the three-surface covering reflective layer, wherein a material of the isolation layer is Al2O3 or Si3N4; a negative electrode pad layer electrically connected to the conductive semiconductor layer; a positive electrode layer electrically connected to the conductive semiconductor layer; and an integrated circuit (IC) chip layer electrically connected to the positive electrode layer.

In some exemplary embodiments or any combination of exemplary embodiments of the micro light-emitting pixel structure, the three-surface covering reflective layer comprises: a middle conductive portion in contact with the positive electrode layer and the conductive semiconductor layer; two side reflection portions in contact with the isolation layer; and two edge reflection portions in contact with the isolation layer; wherein the three-surface covering reflective layer forms a shape of an inverted trapezoid around the quantum well layer.

In some exemplary embodiments or any combination of exemplary embodiments of the micro light-emitting pixel structure, the quantum well layer is enclosed within the inverted trapezoidal shape of the conductive semiconductor layer so that light from the quantum well is focused toward a top direction of the light-emitting pixel structure.

In some exemplary embodiments or any combination of exemplary embodiments of the micro light-emitting pixel structure, the isolation layer forms a shape of an inverted trapezoid around the quantum well layer.

In some exemplary embodiments or any combination of exemplary embodiments of the micro light-emitting pixel structure, the conductive semiconductor layer includes a continuous planarization layer on top of the inverted trapezoidal shape.

In some exemplary embodiments or any combination of exemplary embodiments of the micro light-emitting pixel structure, the continuous planarization layer covers a whole surface of the micro light-emitting pixel structure and extends to an adjacent micro light-emitting pixel structure.

In some exemplary embodiments or any combination of exemplary embodiments of the micro light-emitting pixel structure, the micro light-emitting pixel structure further includes an isolation layer between the conductive semiconductor layer and the three-surface covering reflective layer, wherein a material of the isolation layer is Al2O3 or Si3N4.

In some exemplary embodiments or any combination of exemplary embodiments of the micro light-emitting pixel structure, the negative electrode pad layer is formed above the continuous planarization layer, and is hollowed-out in an area above the quantum well so that light emitting from the quantum well is not blocked by the negative electrode pad layer.

In some exemplary embodiments or any combination of exemplary embodiments of the micro light-emitting pixel structure, the micro light-emitting pixel structure further includes a dielectric layer between the three-surface covering reflective layer and the IC chip layer, wherein the dielectric layer includes a top dielectric layer made of Si3N4 covering a surface of the three-surface covering reflective layer and a bottom dielectric layer made of SiO2.

In some exemplary embodiments or any combination of exemplary embodiments of the micro light-emitting pixel structure, the positive electrode layer includes an upper epitaxial positive electrode and a bottom chip positive electrode, the upper epitaxial positive electrode is within the dielectric layer, and the bottom chip positive electrode is within the IC chip layer.

In some exemplary embodiments or any combination of exemplary embodiments of the micro light-emitting pixel structure, the IC chip layer includes an upper chip dielectric layer and a bottom chip electric plate.

In some exemplary embodiments or any combination of exemplary embodiments of the micro light-emitting pixel structure, the IC chip layer including a bottom chip positive electrode is in contact with the dielectric layer including an upper epitaxial positive electrode.

In some exemplary embodiments or any combination of exemplary embodiments of the micro light-emitting pixel structure, the micro light-emitting pixel structure further includes a pixel lens above the conductive semiconductor layer.

Some exemplary embodiments of the present disclosure include a method of manufacturing a micro light-emitting pixel structure, that includes: providing an epitaxial wafer including a conductive semiconductor layer, and a quantum well layer for light-emitting, wherein the quantum well layer is within the conductive semiconductor layer; etching the conductive semiconductor layer with the quantum well layer into an inverted trapezoidal shape; forming an isolation layer on a bottom surface of the conductive semiconductor layer, wherein a material of the isolation layer is Al2O3 or Si3N4; forming a three-surface covering reflective layer on a bottom surface of the isolation layer, wherein a material of the three-surface covering reflective layer is Ag; forming a first positive electrode layer on bottom surface of a middle conductive portion of the three-surface covering reflective layer; bonding an integrated circuit (IC) chip layer to the first positive electrode layer; and forming a negative electrode pad layer on upper surface of the conductive semiconductor layer.

In some exemplary embodiments or any combination of exemplary embodiments of the method of manufacturing the micro light-emitting pixel structure, the method further includes after forming the three-surface covering reflective layer and before forming the first positive electrode layer, forming a dielectric layer between the three-surface covering reflective layer and the IC chip layer, wherein the dielectric layer includes a top dielectric layer made of Si3N4 covering a surface of the three-surface covering reflective layer and a bottom dielectric layer made of SiO2.

In some exemplary embodiments or any combination of exemplary embodiments of the method of manufacturing the micro light-emitting pixel structure, etching the conductive semiconductor layer with the quantum well layer further comprises leaving a continuous planarization layer on top of the inverted trapezoidal shape in the conductive semiconductor layer.

In some exemplary embodiments or any combination of exemplary embodiments of the method of manufacturing the micro light-emitting pixel structure, the epitaxial wafer includes a sapphire substrate layer, and after bonding the IC chip layer and before forming the negative electrode pad layer, the method further includes removing the sapphire substrate layer.

In some exemplary embodiments or any combination of exemplary embodiments of the method of manufacturing the micro light-emitting pixel structure, forming an isolation layer includes etching the isolation layer to form an opening for deposition of the middle conductive portion of the three-surface covering reflective layer on a bottom surface of the conductive semiconductor layer through the opening.

In some exemplary embodiments or any combination of exemplary embodiments of the method of manufacturing the micro light-emitting pixel structure, forming the dielectric layer includes etching the dielectric layer to form an opening for deposition of the first positive electrode layer.

In some exemplary embodiments or any combination of exemplary embodiments of the method of manufacturing the micro light-emitting pixel structure, bonding includes alignment bonding the IC chip layer embedded with a second positive electrode layer to a bottom surface of the dielectric layer embedded with the first positive electrode layer, wherein first positive electrode layer is an upper epitaxial positive electrode and the second positive electrode layer is bottom chip positive electrode.

In some exemplary embodiments or any combination of exemplary embodiments of the method of manufacturing the micro light-emitting pixel structure, forming the negative electrode pad layer including using a stripping process to form a hollowed-out shape in the negative electrode pad layer in an area above the quantum well so that light emitting from the quantum well is not blocked by the negative electrode pad layer.

In some exemplary embodiments or any combination of exemplary embodiments of the method of manufacturing the micro light-emitting pixel structure, the method further includes after forming a negative electrode pad layer, forming a pixel lens above the conductive semiconductor layer and aligned with the hollowed-out shape in the negative electrode pad layer.

To solve the low light efficiency conversion issues in the conventional light-emitting units, the present disclosure achieves the purpose of improving the light efficiency by the design of the interior of the pixel structure.

In some exemplary embodiments, the present disclosure provides the following technical aspects:

In some embodiments, a pixel structure for reducing the light blocking effect and improving light reflecting efficiency comprises a pixel lens, a negative electrode pad layer, a conductive semiconductor layer, a quantum well, an isolation layer, a positive electrode layer, a dielectric layer and an integrated circuit (IC) chip layer from top to bottom or from outside to inside, wherein the quantum well is arranged in the conductive semiconductor layer.

In some embodiments, a three-surface covering reflective layer is arranged between the lower surface of the conductive semiconductor layer and the top of the positive electrode layer, and the three-surface covering reflective layer covers and conforms to the shape of the bottom surface, the side surface and the bottom surface of an upper surface of the conductive semiconductor layer respectively.

In some embodiments, the conductive semiconductor layer comprises an inverted trapezoidal semiconductor part and a continuous planarization layer. The quantum well is located inside the inverted trapezoidal semiconductor part. The inverted trapezoidal semiconductor part is divided into a P—GaN part at the bottom and an N—GaN part at the top in the horizontal direction of the quantum well. The bevels (inclined sides of the inverted trapezoid) on the two sides of the inverted trapezoidal semiconductor part converge and reflect the light emitted by the quantum well toward the direction of the pixel lens. The continuous planarization layer between a plurality of pixels is integrally and continuously arranged. The top surface of the continuous planarization layer is provided with a negative electrode pad layer, so that the negative electrode pad layer and the conductive semiconductor layer are not located on the same planar layer. The positive electrode layer is arranged in the dielectric layer, and the dielectric layer and the IC chip layer are in an alignment connection.

According to the above structures disclosed herein, the light emitted by the quantum well is reflected by the three-surface covering reflective layer, and the light rays from one side of the quantum well facing away from the surface of the pixel lens are reflected back to the pixel lens, so that the utilization efficiency of the light emitted by the quantum well is greatly improved. Meanwhile, light emitted by the quantum well to the two sides of the pixel lens is reflected by using the bevels of the inverted trapezoidal semiconductor part, so that the light emitted by the quantum well to the two sides of the pixel lens may also be gathered and collected in the direction towards the pixel lens, and the utilization efficiency of the light emitted by the quantum well is further improved. In addition, using the continuous planarization layer structure design, the negative electrode pad layer may be arranged at any position of the continuous planarization layer. In some embodiments, the negative electrode pad layer may be arranged at the position where the quantum well is not blocked to emit light to the pixel lens, so that the negative electrode pad layer does not block the light, and the efficiency of collecting the light by the pixel lens is further improved.

In some embodiments, the three-surface covering reflective layer includes a conductive part, a side reflection part and an edge reflection part. The upper surface of the conductive part is attached to the conductive semiconductor layer, and the lower surface of the conductive part is attached to the positive electrode layer. The upper surface of the side reflection part and the upper surface of the edge reflection part are both attached to the isolation layer, and the lower surface of the side reflection part is attached to the dielectric layer.

In some embodiments, the conductive part has a main reflection effect, and the side reflection part has a residual light reflection effect, and the isolation layer is a transparent layer.

In some embodiments, the three-surface covering reflective layer is or includes an Ag layer formed by electron beam evaporation or thermal evaporation.

In some embodiments, a good reflection effect is achieved by using an Ag layer, and the reflectivity of Ag is highest among the reflective materials.

In some embodiments, the isolation layer is configured as Al2O3 or Si3N4.

In some embodiments, the negative electrode pad layer is hollow, the hollow part of the negative electrode pad layer is provided with the pixel lens, and the main body part of the negative electrode pad layer is arranged at the upper surface position of the continuous planarization layer other than the positions blocking the light ray towards the pixel lens.

According to structures disclosed herein, light rays from the quantum well toward the lens direction of the pixel lens is not blocked by positioning the negative electrode pad layer.

In some embodiments, the dielectric layer comprises a Si3N4 layer structure at the top and a SiO2 layer structure at the bottom, and the Si3N4 layer structure covers and attaches the surface of the three-surface covering reflective layer. The positive electrode comprises an epitaxial positive electrode and a chip positive electrode, while the epitaxial positive electrode is continuously arranged in the Si3N4 layer structure and the SiO2 layer structure in a penetrating configuration, and the chip positive electrode is arranged in the IC chip layer.

In some embodiments, the IC chip layer comprises a chip dielectric layer at the top and a chip electric plate at the bottom, while the chip positive electrode is arranged in the chip dielectric layer in a penetrating configuration, the top of the chip positive electrode is connected to the epitaxial positive electrode by alignment bonding, and the bottom of the chip positive electrode is electrically connected to the chip electric plate.

Due to the fact that the Ag three-surface covering reflective layer is arranged in the pixel structure, and that a traditional pixel process is implemented for manufacturing the pixel structure, the Ag layer loss may occur which further causes the internal short circuit of the pixel structure. In some embodiments, the chip dielectric layer and the dielectric layer alignment bonding connection structure and process are used, so that the non-short-circuit installation of the IC chip layer is achieved.

In some embodiments, the positive electrode layer is configured as a Cu column.

In some exemplary embodiments, the disclose herein provides the following technical aspects:

In some embodiments, based on the pixel internal structure, a pixel structure manufacturing process for reducing the light blocking effect and improving light reflecting efficiency is provided. The pixel structure manufacturing process comprises the following process steps:
Step 1: selecting an epitaxial wafer that, in some embodiment, includes a sapphire layer on the top surface, and a conductive semiconductor layer at the bottom with a quantum well at the middle of the conductive semiconductor layer;
Step 2: semiconductor etching;
Sub-step 2-1 of step 2: Etching the conductive semiconductor layer inside the epitaxial wafer to form the inverted trapezoidal semiconductor part with an inverted trapezoidal shape, wherein the quantum well is located inside the inverted trapezoidal semiconductor part;
Step 3: isolation layer deposition and patterning etching;
Sub-step 3-1 of step 3: forming the isolation layer on the bottom surface of the conductive semiconductor layer;
Sub-step 3-2 of step 3: etching the isolation layer after its deposition is completed, and etching to form an opening at the bottom of the inverted trapezoidal semiconductor part for deposition of the conductive part of the three-surface covering reflective layer;
Step 4: three-surface covering reflective layer deposition and patterning etching;
Sub-step 4-1 of step 4: forming the three-surface covering reflective layer by deposition on the bottom surface of the isolation layer;
Sub-step 4-2 of step 4: trimming to form the shape of the three-surface covering reflective layer;
Step 5: dielectric layer deposition and patterning etching;
Sub-step 5-1 of step 5: forming the dielectric layer by deposition on the lower surface of the three-surface covering reflective layer;
Sub-step 5-2 of step 5: etching and trimming to form the shape of dielectric layer;
Step 6: positive electrode deposition and polishing;
Sub-step 6-1 of step 6: depositing and forming the positive electrode layer;
Sub-step 6-2 of step 6: performing the polishing operation on the positive electrode layer;
Step 7: the alignment bonding;
Sub-step 7-1 of step 7: connecting the IC chip layer with an alignment bonding process to the bottom surface of the dielectric layer;
Step 8: removing the sapphire layer;
Step 9: deposition and patterning of the negative electrode pad layer;
Sub-step 9-1 of step 9: depositing and forming the negative electrode pad layer;
Sub-step 9-2 of step 9: patterning the negative electrode pad layer to form a hollowed-out shape;
Step 10: Lens deposition and patterning;
Sub-step 10-1 of step 10: depositing a layer structure forming the pixel lens;
Sub-step 10-2 of step 10: patterning the layer structure of the pixel lens to form a lens shape.

Through the technical scheme, the novel pixel structure may be manufactured by using the technology.

In some embodiments, an epitaxial wafer in the step 1 comprises a sapphire layer, a conductive semiconductor layer and a quantum well is selected as an initial material processed by a pixel structure process, wherein the conductive semiconductor layer comprises a P-type material, for example, a P—GaN material layer at the bottom of the quantum well and an N-type material, for example, an N—GaN material layer at the top of the quantum well.

In some embodiments, the process of etching the conductive semiconductor layer in the epitaxial wafer in the step 2 is an Inductively Coupled Plasma (ICP) semiconductor etching process, and an inverted trapezoidal or bowl-shaped pattern is formed by etching.

In some embodiments, the process for forming the isolation layer in the step 3 is an atomic layer deposition (ALD) process, and an ICP etching process is implemented for the etching process of the deposited isolation layer.

In some embodiments, the process of forming the three-surface covering reflective layer in the step 4 is a physical vapor deposition (PVD) process of electron beam evaporation or thermal evaporation, and the process of etching the three-surface covering reflective layer implements a stripping process to etch and trim to form the shape.

In some embodiments, the process of forming the dielectric layer in the step 5 is implemented by a chemical vapor deposition (CVD) process method, and etching and trimming to form the shape of the dielectric layer is implemented by an ICP semiconductor etching process.

In some embodiments, the positive electrode layer is formed in the step 6 by implementing an electroplating deposition process, and the positive electrode layer is polished through a chemical mechanical polishing (CMP) process.

In some embodiments, the sapphire layer on the upper surface of the epitaxial wafer is stripped by a laser stripping process in the step 8.

In some embodiments, the negative electrode pad layer is formed by PVD deposition of a physical vapor deposition process of electron beam evaporation or thermal evaporation in the step 9, and the negative electrode pad layer is stripped to form a hollowed-out shape by implementing a stripping process.

In some embodiments, the process in the step 10 is a CVD deposition process to form a layer structure of the pixel lens, and an ICP semiconductor etching process is implemented for the layer structure of the pixel lens to form the pixel lens with a lens shape.

In summary, the systems and methods disclosed herein have the following benefits and improvements:
(1) The light emitted by the quantum well is reflected by the three-surface covering reflective layer, and the light rays from one side of the quantum well facing away from the pixel lens are reflected back the pixel lens, so that the utilization efficiency of the light emitted by the quantum well is greatly improved.
(2) Light emitted by the quantum well to the two sides of the pixel lens is reflected by using the bevels of the inverted trapezoidal semiconductor part, so that the light emitted by the quantum well to the two sides of the pixel lens may also be gathered and collected in the direction towards the pixel lens, and the utilization efficiency of the light emitted by the quantum well is further improved.
(3) The negative electrode pad layer may be arranged at any position of the continuous planarization layer by utilizing the continuous planarization layer structure design. Therefore, the position of the negative electrode pad layer may be arranged at the position where the quantum well is not blocked to emit light to the pixel lens, so that the negative electrode pad layer does not block the light, and the efficiency of collecting the light by the pixel lens is further improved. In the meanwhile, the negative electrode pad layer and the mesa (i.e. the epitaxial wafer, comprising the conductive semiconductor layer(s) including the quantum well as the middle layer) are not in one planar layer, so that a short-circuit condition between the negative electrode pad layer and the three-surface covering reflective layer is not prone to occurring. The positioning of the negative electrode pad layer enables the current diffusion from the top of the pixel structure to the mesa. The positioning of the negative electrode pad layer may further prevent interference between adjacent pixels.
(4) Due to the fact that the three-surface covering reflective layer of the Ag forms a three-surface covering pattern in the processing technology, when the three-surface covering reflective layer is connected to the IC chip layer, the alignment bonding process is implemented, and the epitaxial positive electrode and the chip positive electrode are in a one-to-one alignment and then they are bonded and connected.
(5) A continuous planarization layer between a plurality of pixels implements a continuous design, plays a role of protecting Ag, and is convenient for current diffusion.
(6) An isolation layer of an Al2O3 or Si3N4 material is provided, to isolate three-surface covering reflective layer and the conductive semiconductor layer including the quantum well. The selection of Al2O3 as the isolation layer may prevent the diffusion of Ag because Al2O3 has less lattice defects compared with other traditional materials. The selection of Si3N4 as the isolation layer may prevent the diffusion of Ag because Si3N4 has less lattice defects compared with other traditional materials.
(7) A novel structural design of dividing the dielectric layer into a Si3N4 layer structure at the top and a SiO2 layer structure at the bottom is implemented, wherein the Si3N4 layer structure covers and attaches to the surface of the Ag reflective layer.

Note that the various embodiments described above may be combined with any other embodiments described herein. The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes, and may not have been selected to delineate or circumscribe the inventive subject matter.

### BRIEF DESCRIPTION OF THE DRAWINGS

So that the present disclosure may be understood in greater detail, a more particular description may be had by reference to the features of various embodiments, some of which are illustrated in the appended drawings. The appended drawings, however, merely illustrate pertinent features of the present disclosure and are therefore not to be considered limiting, for the description may admit to other effective features.

For convenience, “up” is used to mean away from the substrate or circuit board/plate of a light emitting structure, “down” means toward the substrate, and other directional terms such as top, bottom, above, below, under, beneath, etc. are interpreted accordingly.

FIG. 1 is an exemplary schematic cross-sectional view of an overall structure of a pixel structure in accordance with some embodiments of the present implementation.

FIG. 2 is an exemplary schematic top view of a pixel structure in accordance with some embodiments of the present implementation.

FIG. 3 is an exemplary schematic structural diagram of Step 1 in a pixel structure manufacturing process in accordance with some embodiments of the present implementation.

FIG. 4 is an exemplary schematic structural diagram of Step 2 in a pixel structure manufacturing process in accordance with some embodiments of the present implementation.

FIG. 5 is an exemplary schematic structural diagram of Step 3 in a pixel structure manufacturing process in accordance with some embodiments of the present implementation.

FIG. 6 is an exemplary schematic structural diagram of Step 4 in a pixel structure manufacturing process in accordance with some embodiments of the present implementation.

FIG. 7 is an exemplary schematic structural diagram of Step 5 in a pixel structure manufacturing process in accordance with some embodiments of the present implementation.

FIG. 8 is an exemplary schematic structural diagram of Step 6 in a pixel structure manufacturing process in accordance with some embodiments of the present implementation.

FIG. 9 is an exemplary schematic structural diagram of Step 7 in a pixel structure manufacturing process in accordance with some embodiments of the present implementation.

FIG. 10 is an exemplary schematic structural diagram of Step 8 in a pixel structure manufacturing process in accordance with some embodiments of the present implementation.

FIG. 11 is an exemplary schematic structural diagram of Step 9 in a pixel structure manufacturing process in accordance with some embodiments of the present implementation.

FIG. 12 is an exemplary schematic structural diagram of Step 10 in a pixel structure manufacturing process in accordance with some embodiments of the present implementation.

The FIGs. include the following identifications of parts: 1, Pixel lens; 2, negative electrode pad layer; 3, the conductive semiconductor layer; 3-1, an inverted trapezoidal semiconductor part; 3-11, a P—GaN part; 3-12, an N—GaN part; 3-2, a continuous planarization layer; 4, a quantum well; 5, an isolation layer; 6, a positive electrode layer; 6-1, an epitaxial positive electrode; 6-2, a chip positive electrode; 7, a dielectric layer; 7-1, a Si3N4 layer structure; 7-2, a SiO2 layer structure; 8, an IC chip layer; 8-1, a dielectric layer of a chip; 8-2, a chip electric plate; 9, a three-surface covering reflective layer; 9-1, a conductive part; 9-2, a side reflection part; and 9-3, an edge reflection part.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

Numerous details are described herein in order to provide a thorough understanding of the example embodiments illustrated in the accompanying drawings.

However, some embodiments may be practiced without many of the specific details, and the scope of the claims is only limited by those features and aspects specifically recited in the claims. Furthermore, well-known processes, components, and materials have not been described in exhaustive detail so as not to unnecessarily obscure pertinent aspects of the embodiments described herein.

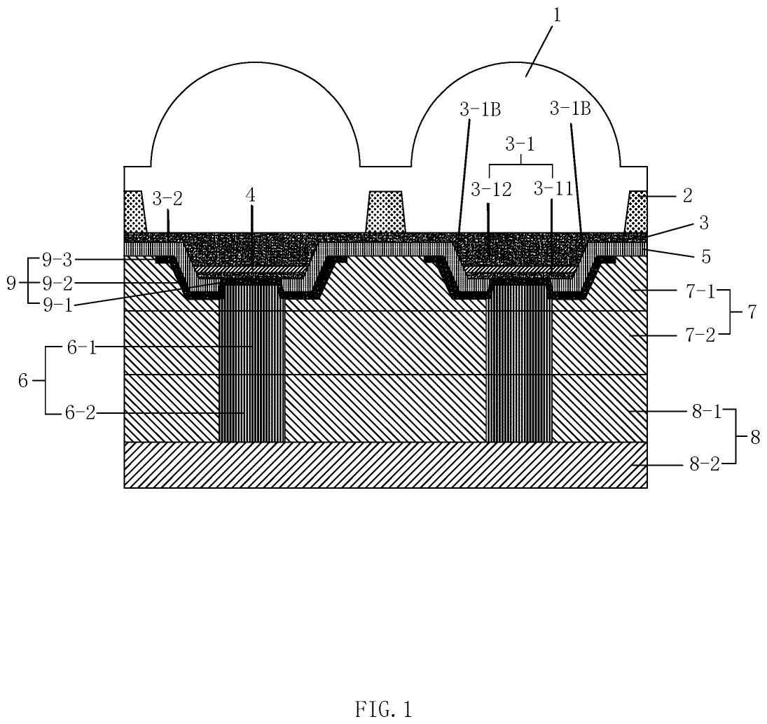

FIG. 1 is an exemplary schematic cross-sectional view of an overall structure of a pixel structure in accordance with some embodiments of the present implementation.

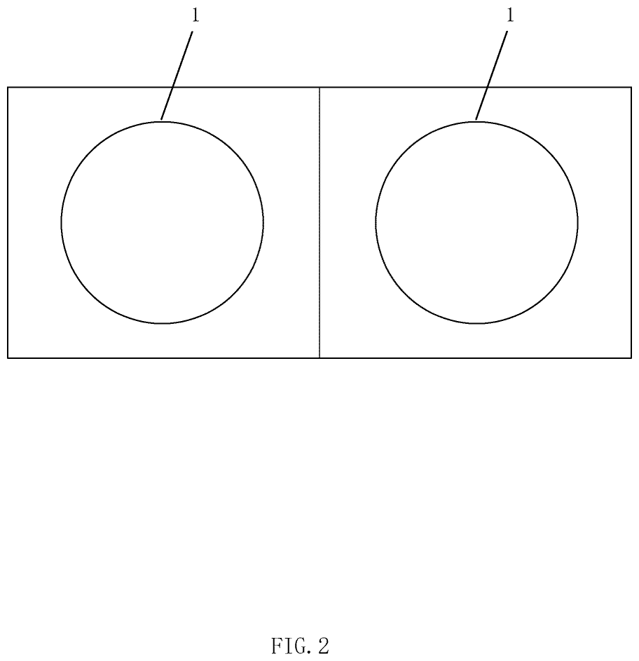

FIG. 2 is an exemplary schematic top view of the pixel structure in accordance with some embodiments of the present implementation.

In some embodiments, the pixel structure configured to reduce the light blocking effect and improving reflecting efficiency is illustrated in FIGS. 1 and 2. Pitch refers to the distance between the centers of adjacent pixels on a display panel. In some embodiments, the pitch may vary from about 40 microns, to about 20 microns, to about 10 microns, and/or preferably to about 5 microns or below. Many efforts have been made to reduce the pitch. A single pixel area is fixed when the pitch specification is determined.

The structure includes a pixel lens 1, a negative electrode pad layer 2, a conductive semiconductor layer 3, a quantum well 4, an isolation layer 5, a positive electrode layer 6, a dielectric layer 7 and an IC chip layer 8 from outside (top) to inside (down). And the quantum well 4 is arranged inside the conductive semiconductor layer 3. The conductive semiconductor layer 3 is made of a GaN semiconductor material, and the positive electrode layer 6 is configured as a Cu column. The overall working principle is described as follows. The quantum well 4 serves as a light-emitting unit. The negative electrode pad layer 2 and the positive electrode layer 6 are respectively grounded and connected to the electrical signal on the IC chip layer 8. And the electrical signal is transmitted inside the pixel through the negative electrode pad layer 2 and positive electrode layer 6, thereby providing a driving signal for the quantum well 4, and controlling whether the quantum well 4 emits light or not. Therefore, the signal control instruction of the IC chip layer 8 enters the inside of the pixel structure through the positive electrode layer 6.

Compared with a traditional pixel structure, the present disclosure provides improved internal details of a pixel structure, so that the processing technology to manufacture the pixel structure is also different, and the purpose is to improve the efficiency of collecting the light emitted by the quantum well 4 in the pixel structure. In some embodiments, specifically, a three-surface covering reflective layer 9 is disposed between the lower surface of the conductive semiconductor layer 3 and the top of the positive electrode layer 6, wherein the three-surface covering reflective layer 9 comprises a conductive portion 9-1, a side reflection portion 9-2, and an edge reflection portion 9-3. The upper surface of the conductive portion 9-1 is in contact with the conductive semiconductor layer 3, and the lower surface of the conductive portion 9-1 is in contact with the positive electrode layer 6. The upper surface of the side reflection portion 9-2 and the upper surface of the edge reflection portion 9-3 are both in contact with the isolation layer 5, and the lower surface of the side reflection portion 9-2 and the upper surface of the edge reflection portion 9-3 are both in contact with the dielectric layer 7. In some embodiments, the three-surface covering reflective layer 9 appear symmetrical with a side reflection portion 9-2, and an edge reflection portion 9-3 on both sides of the three-surface covering reflective layer 9 as shown in FIG. 1. In the present embodiment, the three-surface covering reflective layer 9 is or includes an Ag layer formed by electron beam evaporation or thermal evaporation, although other reflective material layers may also be used. Since the reflection effect of Ag is optimal, Ag is used as a reflective layer material. However, since Ag is a material which is very easy to diffuse during etching, Ag is commonly not used within the internal structure of a pixel device as a reflective layer. In this disclosure, the reflective layer structure of the Ag and the pixel processing technology thereof are described herein.

In some embodiments, the light rays emitted by the quantum well 4 are reflected by the three-surface covering reflective layer 9, and the light rays from one side of the quantum well 4 facing away from the pixel lens 1 are reflected back to the pixel lens 1, so that the utilization efficiency of the light emitted by the quantum well 4 is greatly improved.

In some embodiments, the conductive semiconductor layer 3 comprises two parts of an inverted trapezoidal semiconductor part 3-1 and a continuous planarization layer 3-2. Since the quantum well 4 is located inside the inverted trapezoidal semiconductor part 3-1, the bevels 3-1B of the inverted trapezoidal semiconductor part 3-1 collect and reflect the light rays emitted by the quantum well 4 to the direction of the pixel lens 1. Therefore, the light emitted by the quantum well 4 on the two sides of the pixel lens 1 is reflected by using the bevels of the inverted trapezoidal semiconductor part 3-1, so that light emitted from the two sides of the pixel lens 1 may also be converged and collected in the direction of the pixel lens 1, and the utilization efficiency of the light emitted by the quantum well 4 is further improved. The inverted trapezoidal semiconductor part 3-1 is divided into a bottom part 3-11 and a top part 3-12 along a horizontal direction of the quantum well 4, and the quantum well 4 isolates the bottom part 3-11 from the top part 3-12. In some embodiments, the bottom part 3-11 is a layer including P-type conductive semiconductor material, such as P—GaN, P—InGaP and the top part 3-12 is a layer including N-type conductive semiconductor material, such as N—GaN, N—InGaP. In some embodiments, a transparent thin conductive film, such as an indium tin oxide (ITO) thin film is deposited on the top of the conductive semiconductor layer 3. In some other embodiments, the positions of the P-type and N-type materials may be switched, and the positions of the positive and negative electrode layers may be switched.

Moreover, in some embodiments, the negative electrode pad layer 2 is configured in a hollowed-out shape as shown in FIGS. 1 and 2. The hollow part of the negative electrode pad layer 2 is provided and aligned with the pixel lens 1, and the main body part of the negative electrode pad layer 2 is arranged at the upper surface position of the continuous planarization layer 3-2 other than the positions blocking the light rays towards the pixel lens 1. The main body part of the negative electrode pad layer 2 is protruding from the upper surface position of the continuous planarization layer 3-2. Therefore, by the design of the continuous planarization layer 3-2, the negative electrode pad layer 2 may be arranged at the position where the quantum well 4 emits light to the pixel lens 1, so that the negative electrode pad layer 2 does not block the light, and the efficiency of collecting the light by the pixel lens 1 is further improved. In some embodiments, a mesa is formed by an epitaxial wafer which is (or includes) the conductive semiconductor layer 3 with the quantum well 4 in the middle as shown in FIG. 1. A mesa is a light emitting PN junction. At the same time, the negative electrode pad layer and the mesa are not in one planar layer, so that a short-circuit condition between the negative electrode pad layer and the three-surface covering reflective layer 9 is not likely to occur.

In some exemplary embodiments, the isolation layer 5 between the mesa and the three-surface covering reflective layer 9 and dielectric layer 7 is configured as a Al2O3 or Si3N4 material layer manufactured by deposition and etching.

Due to the fact that the Ag three-surface covering reflective layer 9 is arranged in the pixel structure, when a traditional pixel manufacturing process is used for manufacturing the pixel structure, it causes the Ag layer loss which further causes the internal short circuit of the pixel structure. In some embodiments, in the present disclosure, the dielectric layer 7 comprises a double-layer structure of the Si3N4 layer structure 7-1 at the top and the SiO2 layer structure 7-2 at the bottom, and the Si3N4 layer structure 7-1 covers and is in contact with the surface of the three-surface covering reflective layer 9. The positive electrode layer 6 comprises an epitaxial positive electrode 6-1 and a chip positive electrode 6-2, while the epitaxial positive electrode 6-1 is arranged in the Si3N4 layer structure 7-1 and the SiO2 layer structure 7-2 continuously, and the chip positive electrode 6-2 is arranged in the IC chip layer 8. Meanwhile, the IC chip layer 8 comprises a top chip dielectric layer 8-1 and a bottom chip electric plate 8-2. While the chip positive electrode 6-2 penetrates through the chip dielectric layer 8-1, the top of the chip positive electrode 6-2 is connected through bonding according to a location alignment to the epitaxial positive electrode 6-1, and the bottom of the chip positive electrode 6-2 is electrically connected with the chip electric plate 8-2. The two electrodes epitaxial positive electrode 6-1 and a chip positive electrode 6-2 are on two wafers before bonding, and after bonding they form a union. The positive electrode layer 6 is configured as a Cu column. In some embodiments, according to the above structure arrangement and connection mode, the manufacturing of the pixel structure may be realized, that is, the reflective layer forms a three-surface covering pattern in the manufacturing process, then the alignment bonding process is utilized for connections in a later stage.

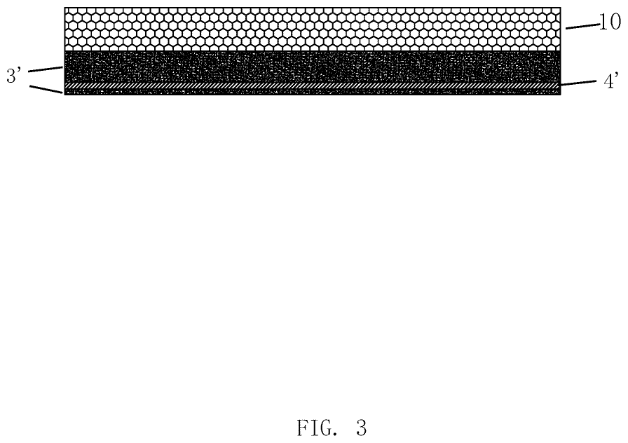

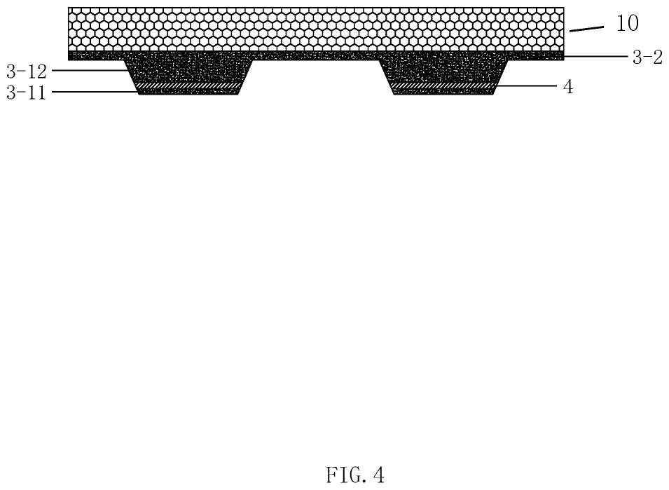

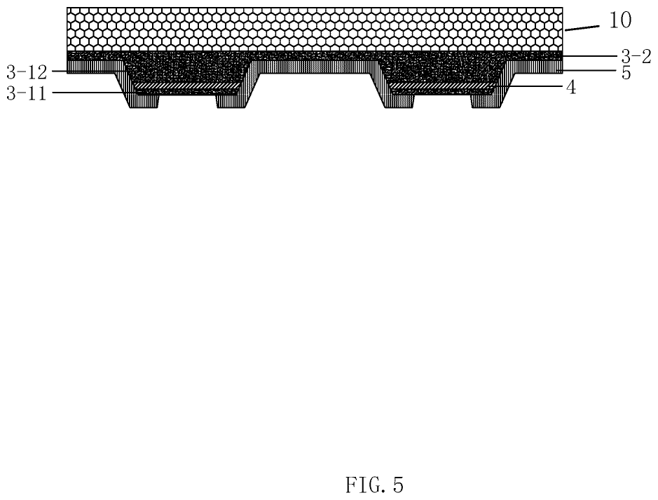

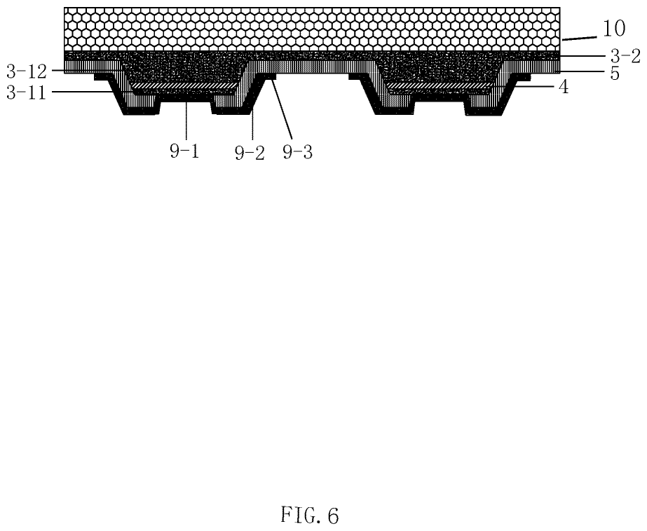

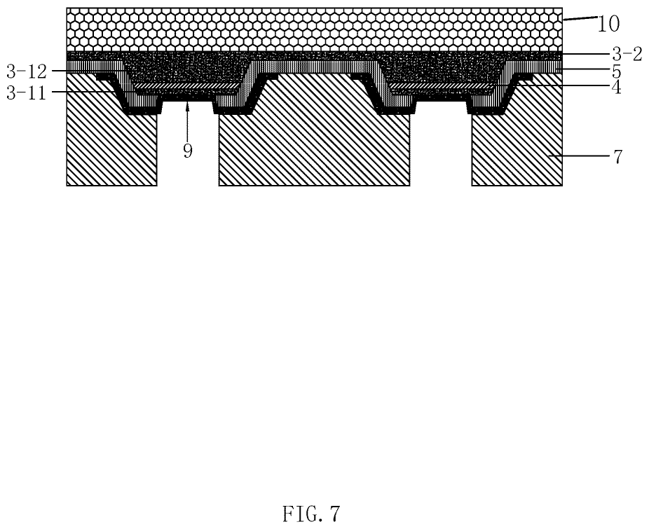

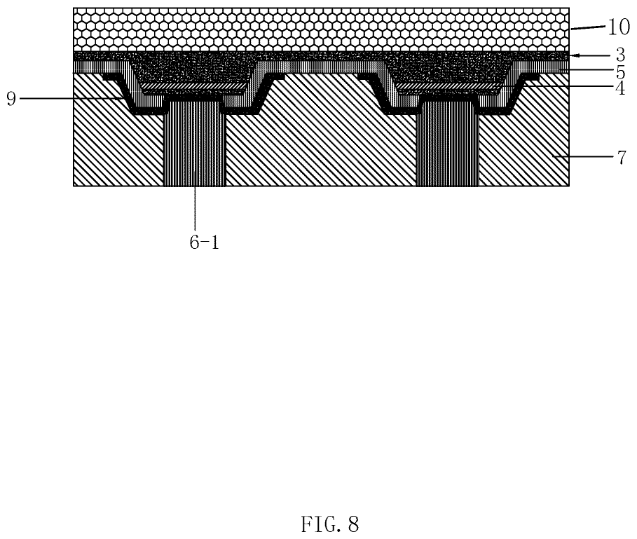

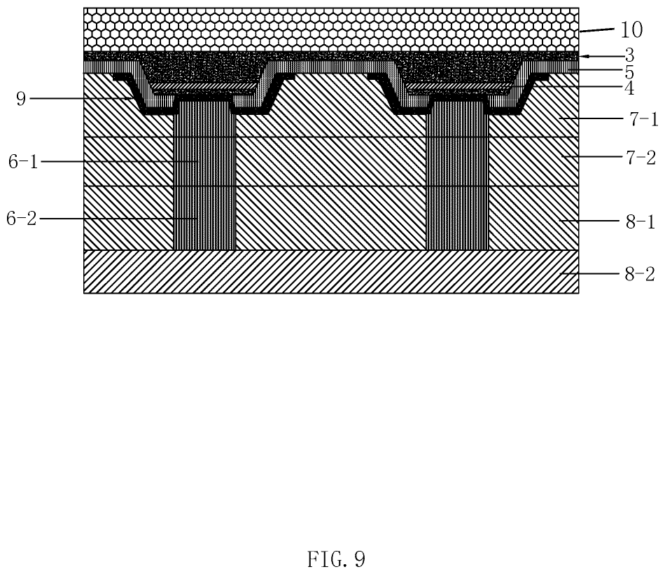

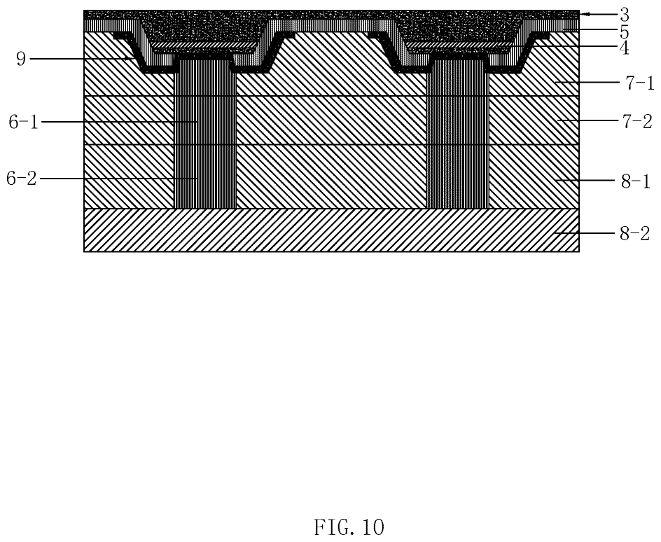

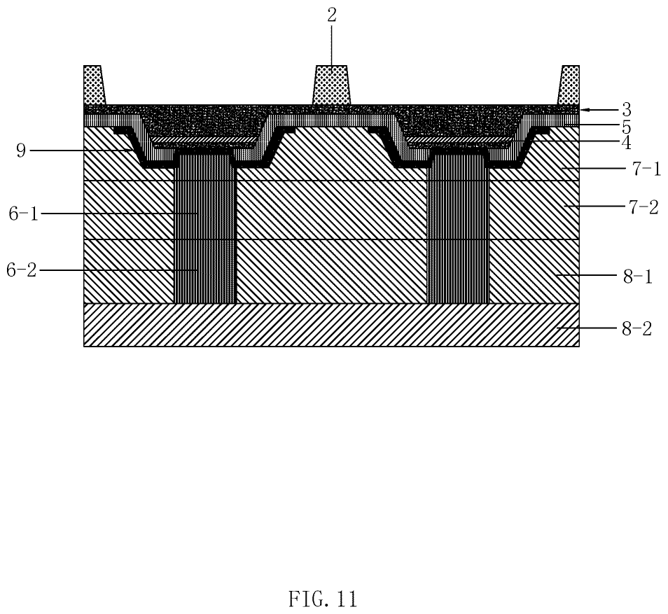

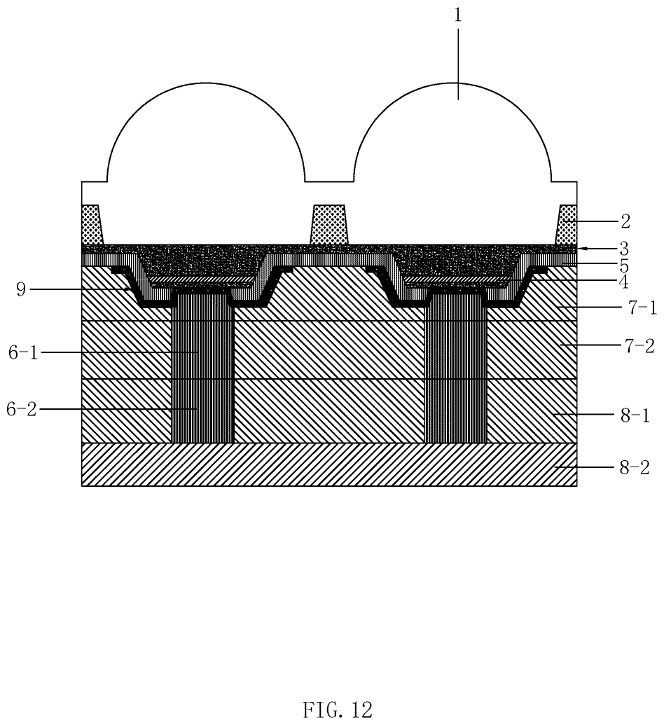

According to the structural design described above inside the pixel, the present embodiment provides a pixel structure manufacturing process for reducing the light blocking effect and improving light reflecting efficiency. The process comprises the following processing steps:
Step 1: Selecting an epitaxial wafer. FIG. 3 is an exemplary schematic structural diagram of Step 1 in a pixel structure manufacturing process in accordance with some embodiments of the present implementation. According to FIG. 3, an epitaxial wafer comprising a sapphire layer 10, a conductive semiconductor layer 3′ and a quantum well 4′ is selected as an initial material by a pixel structure manufacturing process. In some embodiments, the conductive semiconductor layer 3′ comprises a P—GaN material layer at the bottom of the quantum well 4′ and an N—GaN material layer at the top of the quantum well 4′.
Step 2: Semiconductor etching. FIG. 4 is an exemplary schematic structural diagram of Step 2 in a pixel structure manufacturing process in accordance with some embodiments of the present implementation. According to FIG. 4, an ICP semiconductor etching process is used to etch the conductive semiconductor layer 3′ from FIG. 3 inside the epitaxial wafer to form an inverted trapezoidal semiconductor part 3-1 in an inverted trapezoidal shape and a continuous planarization layer 3-2. And the etched quantum well 4 is located inside the inverted trapezoidal semiconductor part 3-1. The inverted trapezoidal semiconductor part 3-1 is etched to form a P—GaN part 3-11 at the bottom and an N—GaN part 3-12 at the top in the horizontal direction of the quantum well 4.
Step 3: Isolation layer deposition and patterning etching. FIG. 5 is an exemplary schematic structural diagram of Step 3 in a pixel structure manufacturing process in accordance with some embodiments of the present implementation. According to FIG. 5, the method includes two sub-steps: (A) depositing an ALD layer via the deposition process on the bottom surface of the conductive semiconductor layer 3 to form an isolation layer 5 (original shape of the isolation layer 5 after deposition is not shown in FIG. 5), wherein the isolation layer 5 is deposited by using an Al2O3 or Si3N4 material; and (B) etching the deposited isolation layer 5 to form the isolation layer 5 with an opening shown in FIG. 5, and etching the bottom of the inverted trapezoidal semiconductor part 3-1 by using an ICP etching process to form an opening (not completely shown in FIG. 5) for deposition of the conductive part 9-1 of the three-surface covering reflective layer 9.
Step 4: Three-surface covering reflective layer deposition and patterning etching. FIG. 6 is an exemplary schematic structural diagram of Step 4 in a pixel structure manufacturing process in accordance with some embodiments of the present implementation. According to FIG. 6, the method includes two sub-steps: (A) using a PVD process of electron beam evaporation or thermal evaporation on the bottom surface of the isolation layer 5 to form a three-surface covering reflective layer 9 (original shape of the reflective layer 9 after deposition is not shown in FIG. 6). In the present embodiment, an Ag material is used as a reflective layer 9; and (B) the three-surface covering reflective layer 9 is etched and trimmed into a shape by using a stripping process.
Step 5: Dielectric layer deposition and patterning etching. FIG. 7 is an exemplary schematic structural diagram of Step 5 in a pixel structure manufacturing process in accordance with some embodiments of the present implementation. According to FIG. 7, the method includes two sub-steps: (A) forming a dielectric layer 7 (original shape of the dielectric layer 7 after deposition is not shown in FIG. 7) by using a CVD deposition process on the lower surface of the three-surface covering reflective layer 9, wherein the dielectric layer 7 is divided into a double-layer structure of a Si3N4 layer structure 7-1 at the top and a SiO2 layer structure 7-2 at the bottom as shown in FIG. 1; and (B) etching and trimming the dielectric layer 7 into a shape by using an ICP semiconductor etching process to leave a space for the positive electrode layer 6.
Step 6: Positive electrode deposition and polishing. FIG. 8 is an exemplary schematic structural diagram of Step 6 in a pixel structure manufacturing process in accordance with some embodiments of the present implementation. According to FIG. 8, the method includes two sub-steps: (A) depositing a positive electrode layer 6 by using an electroplating process deposition method, that is, depositing to form an epitaxial positive electrode 6-1; and (B) performing a polishing operation on the epitaxial positive electrode 6-1 by using a CMP polishing process.
Step 7: Alignment bonding. FIG. 9 is an exemplary schematic structural diagram of Step 7 in a pixel structure manufacturing process in accordance with some embodiments of the present implementation. According to FIG. 9, the bottom surface of the dielectric layer 7 is connected to the IC chip layer 8 by using an alignment bonding process, in which the epitaxial positive electrode 6-1 and the chip positive electrode 6-2 are aligned and bonded to each other. Alignment bonding is normally done between wafers having patterns on each surface. In some embodiments, the sapphire layer 10 and IC chip layer 8 both have patterned electrode (copper) and SiO2 on their surfaces. For the alignment bonding between them, electrodes from two wafers are well aligned face to face. Then the two wafers contact and form an initial bonding. The bonding is finished by a following annealing process, which enhances the bonding strength between copper and copper, and SiO2 and SiO2 contacts.
Step 8: Removing the sapphire layer 10. FIG. 10 is an exemplary schematic structural diagram of Step 8 in a pixel structure manufacturing process in accordance with some embodiments of the present implementation. According to FIG. 10, the sapphire layer 10 on the upper surface of the epitaxial wafer is stripped by a laser lift-off process.
Step 9: Negative electrode pad layer deposition and patterning. FIG. 11 is an exemplary schematic structural diagram of Step 9 in a pixel structure manufacturing process in accordance with some embodiments of the present implementation. According to FIG. 11, the method includes two sub-steps: (A) using a PVD process for electron beam evaporation or thermal evaporation to form a negative electrode pad layer 2 (the original shape of the negative electrode pad layer 2 after PVD is not shown in FIG. 11); and (B) stripping the negative electrode pad layer 2 by using a stripping process to form a hollowed-out shape.
Step 10: Lens Deposition and Patterning. FIG. 12 is an exemplary schematic structural diagram of Step 10 in a pixel structure manufacturing process in accordance with some embodiments of the present implementation. According to FIG. 12, the method includes two sub-steps: (A) using a CVD deposition process to form a layer structure of a pixel lens 1 (original shape of the pixel lens 1 layer after deposition is not shown in FIG. 12); and (B) etching a layer structure of the pixel lens 1 by using an ICP semiconductor etching process to form a lens shape pixel lens 1. In another example, the lens 1 is formed by a CVD deposition process through self-assembly by directly forming a lens shape on the underlying structure without etching. In some examples, the lens 1 is aligned with the hollowed-out shape. For example, the edge of the lens 1 and the edge of the hollowed-out shape are substantially aligned to each other from a vertical view.

The size used in the manufacturing process is following a micro-LED product pixel structure design. In some embodiments, the following size design is implemented, for example, the diameter of the circular part of the pixel lens 1 is 3.2±0.8 μm, the bottom thickness (for instance, not including the focal lens part) of the pixel lens 1 is 1±1 μm, the top width of the inverted trapezoidal semiconductor part 3-1 is 2.05 to 3.8μm, the thickness of the continuous planarization layer 3-2 is 0.01 μm-0.2 μm, the diameter of the epitaxial positive electrode 6-1 and the chip positive electrode 6-2 is 1 μm, the height of the negative electrode pad layer 2 is from 100 nm to 1 μm, the thickness of the isolation layer 5 is from 10 nm to 200 nm, and other sizes are designed according to the design requirements of the product.

In the manufacturing process of the pixel structure, the current disclosure relates to some special processing methods. The method comprises the following processes: an ICP semiconductor etching process, an ALD process, a PVD process, a LIFT-OFF process, a CVD process, an electroplating deposition process, a CMP polishing process, an alignment bonding process, and a laser stripping process,. The technical methods may be understood by a person of ordinary skill in the art.

It is understood by those skilled in the art that, the pixel structure is not limited by the structure mentioned above, and may include more or less components than those as illustrated, or some components may be combined, or a different component may be utilized.

The above descriptions are merely embodiments of the present disclosure, and the present disclosure is not limited thereto. A modifications, equivalent substitutions and improvements made without departing from the conception and principle of the present disclosure shall fall within the protection scope of the present disclosure.

Further embodiments also include various subsets of the above embodiments including embodiments as shown in FIGS. 1-12 combined or otherwise re-arranged in various other embodiments.

Although the detailed description contains many specifics, these should not be construed as limiting the scope of the disclosure but merely as illustrating different examples and aspects of the disclosure. It should be appreciated that the scope of the disclosure includes other embodiments not discussed in detail above. For example, the approaches described above may be applied to the integration of functional devices other than LEDs and OLEDs with control circuitry other than pixel drivers. Examples of non-LED devices include vertical cavity surface emitting lasers (VCSEL), photodetectors, micro-electro-mechanical system (MEMS), silicon photonic devices, power electronic devices, and distributed feedback lasers (DFB). Examples of other control circuitry include current drivers, voltage drivers, trans-impedance amplifiers, and logic circuits.

The preceding description of the disclosed embodiments is provided to enable any person skilled in the art to make or use the embodiments described herein and variations thereof. Various modifications to these embodiments will be readily apparent to those skilled in the art, and the generic principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

Features of the present disclosure may be implemented in, using, or with the assistance of a computer program product, such as a storage medium (media) or computer readable storage medium (media) having instructions stored thereon/in which may be used to program a processing system to perform any of the features presented herein. The storage medium may include, but is not limited to, high-speed random access memory, such as DRAM, SRAM, DDR RAM or other random access solid state memory devices, and may include non-volatile memory, such as one or more magnetic disk storage devices, optical disk storage devices, flash memory devices, or other non-volatile solid state storage devices. Memory optionally includes one or more storage devices remotely located from the CPU(s). Memory or alternatively the non-volatile memory device(s) within the memory, comprises a non-transitory computer readable storage medium.

Stored on any machine readable medium (media), features of the present disclosure may be incorporated in software and/or firmware for controlling the hardware of a processing system, and for enabling a processing system to interact with other mechanisms utilizing the results of the present disclosure. Such software or firmware may include, but is not limited to, application code, device drivers, operating systems, and execution environments/containers.

It will be understood that, although the terms “first,” “second,” etc. may be used herein to describe various elements or steps, these elements or steps should not be limited by these terms. These terms are only used to distinguish one element or step from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art to best utilize the disclosure and the various embodiments.

1. A micro light-emitting pixel structure, comprising:
a conductive semiconductor layer, wherein the conductive semiconductor layer has an inverted trapezoidal shape and includes a continuous layer on top of the inverted trapezoidal shape;
a quantum well layer for light-emitting, wherein the quantum well layer is within the conductive semiconductor layer;
a three-surface covering reflective layer beneath the conductive semiconductor layer, wherein a material of the three-surface covering reflective layer is Ag;
a negative electrode pad layer electrically connected to the conductive semiconductor layer; and
a positive electrode layer electrically connected to the conductive semiconductor layer.

2. (canceled)

3. The micro light-emitting pixel structure according to claim 1, wherein the three-surface covering reflective layer comprises:
a middle conductive portion in contact with the positive electrode layer and the conductive semiconductor layer;
two side reflection portions in contact with the isolation layer; and
two edge reflection portions in contact with the isolation layer;
wherein the three-surface covering reflective layer forms a shape of an inverted trapezoid around the quantum well layer.

4. The micro light-emitting pixel structure according to claim 1, wherein the quantum well layer is enclosed within the inverted trapezoidal shape of the conductive semiconductor layer so that light from the quantum well is focused toward a top direction of the light-emitting pixel structure.

5. The micro light-emitting pixel structure according to claim 1, wherein the isolation layer forms a shape of an inverted trapezoid around the quantum well layer; and
the isolation layer is a continuous layer having at least one opening at the bottom of the inverted trapezoid.

6. (canceled)

7. The micro light-emitting pixel structure according to claim 1, wherein the continuous layer covers a whole surface of the micro light-emitting pixel structure and extends to an adjacent micro light-emitting pixel structure.

8. The micro light-emitting pixel structure according to claim 1, further comprising an isolation layer between the conductive semiconductor layer and the three-surface covering reflective layer, wherein a material of the isolation layer is Al₂O₃ or Si₃N₄.

9. The micro light-emitting pixel structure according to claim 1, wherein the negative electrode pad layer is formed above the continuous layer, and is hollowed-out in an area above the quantum well so that light emitting from the quantum well is not blocked by the negative electrode pad layer.

10. The micro light-emitting pixel structure according to claim 1, further comprising a dielectric layer between the three-surface covering reflective layer and the IC chip layer, wherein the dielectric layer includes a top dielectric layer made of Si₃N₄ covering a surface of the three-surface covering reflective layer and a bottom dielectric layer made of SiO₂.

11. The micro light-emitting pixel structure according to claim 10, wherein the positive electrode layer includes an upper epitaxial positive electrode and a bottom chip positive electrode, the upper epitaxial positive electrode is within the dielectric layer, and the bottom chip positive electrode is within the IC chip layer.

12. The micro light-emitting pixel structure according to claim 1, wherein the IC chip layer includes an upper chip dielectric layer and a bottom chip electric plate.

13. The micro light-emitting pixel structure according to claim 10, wherein the IC chip layer including a bottom chip positive electrode is in contact with the dielectric layer including an upper epitaxial positive electrode.

14. The micro light-emitting pixel structure according to claim 1, further comprising a pixel lens above the conductive semiconductor layer.

15. A method of manufacturing a micro light-emitting pixel structure, comprising:
providing an epitaxial wafer including a conductive semiconductor layer, and a quantum well layer for light-emitting, wherein the quantum well layer is within the conductive semiconductor layer;
etching the conductive semiconductor layer with the quantum well layer into an inverted trapezoidal shape;
forming an isolation layer on a bottom surface of the conductive semiconductor layer, wherein a material of the isolation layer is Al₂O₃ or Si₃N₄;
forming a three-surface covering reflective layer on a bottom surface of the isolation layer, wherein a material of the three-surface covering reflective layer is Ag;
forming a first positive electrode layer on bottom surface of a middle conductive portion of the three-surface covering reflective layer;
bonding an integrated circuit (IC) chip layer to the first positive electrode layer; and
forming a negative electrode pad layer on upper surface of the conductive semiconductor layer.

16. The method according to claim 15, further comprising after forming the three-surface covering reflective layer and before forming the first positive electrode layer, forming a dielectric layer between the three-surface covering reflective layer and the IC chip layer, wherein the dielectric layer includes a top dielectric layer made of Si₃N₄ covering a surface of the three-surface covering reflective layer and a bottom dielectric layer made of SiO₂.

17. The method according to claim 15, wherein etching the conductive semiconductor layer with the quantum well layer further comprises leaving a continuous layer on top of the inverted trapezoidal shape in the conductive semiconductor layer.

18. The method according to claim 15, wherein the epitaxial wafer includes a sapphire substrate layer, and after bonding the IC chip layer and before forming the negative electrode pad layer, the method further includes removing the sapphire substrate layer.

19. The method according to claim 15, wherein forming an isolation layer includes etching the isolation layer to form an opening for deposition of the middle conductive portion of the three-surface covering reflective layer on a bottom surface of the conductive semiconductor layer through the opening.

20. The method according to claim 16, wherein forming the dielectric layer includes etching the dielectric layer to form an opening for deposition of the first positive electrode layer.

21. The method according to claim 16, wherein bonding includes alignment bonding the IC chip layer embedded with a second positive electrode layer to a bottom surface of the dielectric layer embedded with the first positive electrode layer, wherein first positive electrode layer is an upper epitaxial positive electrode and the second positive electrode layer is bottom chip positive electrode.

22. The method according to claim 15, wherein forming the negative electrode pad layer including using a stripping process to form a hollowed-out shape in the negative electrode pad layer in an area above the quantum well so that light emitting from the quantum well is not blocked by the negative electrode pad layer.

23. The method according to claim 22, further comprising after forming a negative electrode pad layer, forming a pixel lens above the conductive semiconductor layer and aligned with the hollowed-out shape in the negative electrode pad layer.

24. The micro light-emitting pixel structure according to claim 1, wherein the conductive semiconductor layer comprises a P-type conductive semiconductor layer and a N-type conductive semiconductor layer.

25. The micro light-emitting pixel structure according to claim 24, wherein
the P-type conductive semiconductor layer is a P—GaN layer or a P—InGaP layer;
the P-type conductive semiconductor layer is a P—GaN layer or a P—InGaP layer, and the N-type conductive semiconductor layer is a N—GaN layer or a N—InGaP layer; or
the N-type conductive semiconductor layer is a N—GaN layer or a N—InGaP layer.

26. The micro light-emitting pixel structure according to claim 1, further comprising an integrated circuit (IC) chip layer electrically connected to the positive electrode layer.

27. The micro light-emitting pixel structure according to claim 1, wherein the continuous layer is a continuous planarization layer.

28. The micro light-emitting pixel structure according to claim 1, wherein the positive electrode layer is configured as a Cu column.

29. A micro light-emitting pixel structure, comprising:
a conductive semiconductor layer, wherein the conductive semiconductor layer has an inverted trapezoidal shape;
a quantum well layer for light-emitting, wherein the quantum well layer is within the conductive semiconductor layer;
a three-surface covering reflective layer beneath the conductive semiconductor layer, wherein a material of the three-surface covering reflective layer is Ag;
an isolation layer between the conductive semiconductor layer and the three-surface covering reflective layer, wherein a material of the isolation layer is Al₂O₃ or Si₃N₄;
a negative electrode pad layer electrically connected to the conductive semiconductor layer; and
a positive electrode layer electrically connected to the conductive semiconductor layer.

30. The micro light-emitting pixel structure according to claim 29, wherein the three-surface covering reflective layer comprises:
a middle conductive portion in contact with the positive electrode layer and the conductive semiconductor layer;
two side reflection portions in contact with the isolation layer; and
two edge reflection portions in contact with the isolation layer;
wherein the three-surface covering reflective layer forms a shape of an inverted trapezoid around the quantum well layer.

31. The micro light-emitting pixel structure according to claim 29, wherein the quantum well layer is enclosed within the inverted trapezoidal shape of the conductive semiconductor layer so that light from the quantum well is focused toward a top direction of the light-emitting pixel structure.

32. The micro light-emitting pixel structure according to claim 29, wherein the isolation layer forms a shape of an inverted trapezoid around the quantum well layer; and
the isolation layer is a continuous layer having at least one opening at the bottom of the inverted trapezoid.

33. The micro light-emitting pixel structure according to claim 29, wherein the conductive semiconductor layer includes a continuous layer on top of the inverted trapezoidal shape.

34. The micro light-emitting pixel structure according to claim 33, wherein the continuous layer covers a whole surface of the micro light-emitting pixel structure and extends to an adjacent micro light-emitting pixel structure.

35. The micro light-emitting pixel structure according to claim 33, wherein the negative electrode pad layer is formed above the continuous layer, and is hollowed-out in an area above the quantum well so that light emitting from the quantum well is not blocked by the negative electrode pad layer.

36. The micro light-emitting pixel structure according to claim 29, further comprising a dielectric layer between the three-surface covering reflective layer and the IC chip layer, wherein the dielectric layer includes a top dielectric layer made of Si₃N₄ covering a surface of the three-surface covering reflective layer and a bottom dielectric layer made of SiO₂.

37. The micro light-emitting pixel structure according to claim 36, wherein the positive electrode layer includes an upper epitaxial positive electrode and a bottom chip positive electrode, the upper epitaxial positive electrode is within the dielectric layer, and the bottom chip positive electrode is within the IC chip layer.

38. The micro light-emitting pixel structure according to claim 29, wherein the IC chip layer includes an upper chip dielectric layer and a bottom chip electric plate.

39. The micro light-emitting pixel structure according to claim 36, wherein the IC chip layer including a bottom chip positive electrode is in contact with the dielectric layer including an upper epitaxial positive electrode.

40. The micro light-emitting pixel structure according to claim 29, further comprising a pixel lens above the conductive semiconductor layer.

41. The micro light-emitting pixel structure according to claim 29, wherein the conductive semiconductor layer comprises a P-type conductive semiconductor layer and a N-type conductive semiconductor layer.

42. The micro light-emitting pixel structure according to claim 41, wherein
the P-type conductive semiconductor layer is a P—GaN layer or a P—InGaP layer;
the P-type conductive semiconductor layer is a P—GaN layer or a P—InGaP layer, and the N-type conductive semiconductor layer is a N—GaN layer or a N—InGaP layer; or
the N-type conductive semiconductor layer is a N—GaN layer or a N—InGaP layer.

43. The micro light-emitting pixel structure according to claim 29, further comprising an integrated circuit (IC) chip layer electrically connected to the positive electrode layer.

44. The micro light-emitting pixel structure according to claim 29, wherein the continuous layer is a continuous planarization layer.

45. The micro light-emitting pixel structure according to claim 29, wherein the positive electrode layer is configured as a Cu column.
